(19) United States
(12) Patent Application Publication
(10) Pub. No.: US 2009/0141247 A1
(43) Pub. Date: Jun. 4, 2009

(54) HEAT SINK AND APPARATUS FOR PROJECTING IMAGE HAVING THE SAME

(75) Inventor: Pil Yong OH, Suwon-si (KR)

Correspondence Address: STANZIONE & KIM, LLP, 919 18TH STREET, N.W., SUITE 440, WASHINGTON, DC, 20006, US

(73) Assignee: Samsung Electronics Co.,Ltd, Suwon-si (KR)

(21) Appl. No.: 12/272,907

(22) Filed: Nov. 18, 2008

(30) Foreign Application Priority Data
Nov. 29, 2007 (KR) 2007-123074

(51) Int. Cl. G03B 21/16; H05K 7/20

(52) U.S. Cl. 353/61; 361/710

(57) ABSTRACT

Disclosed are a heat sink for cooling a light source unit, particularly laser light sources, and an apparatus for projecting an image having the same. The heat sink includes a heat dissipation unit for cooling a light source unit, and the heat dissipation unit includes a duct part for forming a space, into which the heat of the light source unit is discharged, and guiding air, and heat dissipation fins formed integrally with the duct part.

### CROSS-REFERENCE TO RELATED APPLICATIONS

This application claims the benefit of Korean Patent Application No. 2007-0123074, filed Nov. 29, 2007, in the Korean Intellectual Property Office, the disclosure of which is incorporated herein by reference.

### BACKGROUND OF THE INVENTION

1. Field of the Invention

The present invention relates to a heat sink and an apparatus for projecting an image having the same, and more particularly, to a heat sink for cooling laser light sources and an apparatus for projecting an image having the same.

2. Description of the Related Art

In general, a display device includes an optical system including display elements, and a light source for supplying light to the optical system, and uses light emitting diodes (LED) or laser diodes as the light source.

LEDs, which are diodes made of potassium, phosphorous, or arsenic, are used in a display device forming an image, such as a TV or a monitor. The LEDs have several advantages, such as a long life span, little possibility of generation of harmful substances, and free formation of colors, thus being widely applied.

Laser diodes have been increasingly used as a light source of a display device having high-definition image. In order to apply a laser beam to a display device, the laser beam must have a small size and a high output. The laser diodes satisfy these requirements. That is, in order to obtain a small-size and high-output laser beam, a plurality of laser diodes are integrated into a chip array such that respective output beams of the laser beams are converged onto lenses or fibers so as to obtain a high output.

These LEDs or laser diodes are heat generating elements, which generate heat of a high temperature when a display device is driven. Since the lack of effective heat dissipation measures lowers the performance and life span of a product, a heat dissipation structure, which effectively dissipates heat, generated by driving, through a heat dissipation device, is essentially required.

Korean Patent Registration No. 10-0704669 discloses a LED cooling device.

The LED cooling device disclosed in the above patent includes a heat absorption member for absorbing the heat of LEDs, and a cooling unit contacting the heat absorption member for cooling heat conducted from the heat absorbing member, and the cooling unit includes a heat conduction member contacting the heat absorption member for conducting the heat of the heat absorption member, heat dissipation fins surrounding the heat conduction member for dissipating the heat of the heat conduction member, a cooling fan for rapidly cooling the heat dissipated from the heat dissipation fins, and a duct for discharging heat-exchanged air to the outside.

The LED cooling device having the above constitution effectively discharges heat of the LEDs.

However, the above conventional LED cooling device requires separate components including the heat conduction member, the heat dissipation fins, the duct, and the cooling fan, thus having several problems, such an increase in the cost of materials, an increase in the cost of assembly of the components, and a difficulty in obtaining a compact size.

Further, the duct, which is an injection molded product, is excited by the vibration of the cooling fan, and thus generates noise. Therefore, an anti-vibration member for preventing this noise is required.

### SUMMARY OF THE INVENTION

Therefore, one aspect of the invention is to provide a heat sink, which reduces the cost of production, and an apparatus for projecting an image having the same.

Another aspect of the invention is to provide a heat sink, which has a simple shape so as to enhance space utilization, and an apparatus for projecting an image having the same.

In accordance with one aspect, the present invention provides a heat sink comprising a heat dissipation unit for cooling a light source unit, wherein the heat dissipation unit includes a duct part for forming a space, into which the heat of the light source unit is discharged and for guiding air, and heat dissipation fins formed integrally with the duct part.

The heat dissipation unit may be produced by extrusion molding using a metal.

Holding parts for fixing the light source unit may be formed on the heat dissipation unit.

The heat sink may further comprise a cooling fan connected directly to the heat dissipation unit so as to cool the heat dissipation fins.

The heat dissipation unit may further include a chamber part provided between the light source unit and the duct part so as to promote the diffusion of heat.

The chamber part may maintain a vacuum state, and be filled with a designated amount of a liquid.

The light source unit may be applied to an apparatus for projecting an image.

The light source unit may include laser light sources.

The heat dissipation fins may be formed integrally with the inside of the duct part.

In accordance with another aspect, the present invention provides an apparatus for projecting an image, comprising a light source unit, and a heat sink for cooling the light source unit, wherein the heat sink includes a heat dissipation unit including a duct part for forming a space, into which the heat of the light source unit is discharged, and guiding air, and heat dissipation fins formed integrally with the duct part; and a cooling fan connected directly to one side of the heat dissipation unit.

The light source unit may be held on one surface of the heat dissipation unit; and the heat dissipation unit may further include a chamber part provided between the light source unit and the duct part so as to promote the diffusion of heat.

The chamber part may maintain a vacuum state, and be filled with a designated amount of a liquid.

The light source unit may include laser light sources.

The heat dissipation unit may be produced by extrusion molding using a metal.

### BRIEF DESCRIPTION OF THE DRAWINGS

These and/or other aspects and advantages of the invention will become apparent and more readily appreciated from the following description of the embodiments, taken in conjunction with the accompanying drawings in which:

FIG. 1 is a view illustrating an apparatus for projecting an image in accordance with a preferred embodiment of the present invention;

FIG. 2 is an assembled perspective view illustrating a light source unit and a heat sink for cooling the light source unit in the apparatus for projecting an image in accordance with the preferred embodiment of the present invention;

FIG. 3 is an exploded perspective view of FIG. 2;

FIG. 4 is a cross-sectional view of FIG. 2; and

FIGS. 5A to 5C are views illustrating a process for manufacturing the heat sink in accordance with the preferred embodiment of the present invention.

### DETAILED DESCRIPTION OF THE PREFERRED EMBODIMENTS

Reference will now be made in detail to the embodiments of the present invention, an example of which is illustrated in the accompanying drawings, wherein like reference numerals refer to like elements throughout. The embodiments are described below to explain the present invention by referring to the annexed drawings.

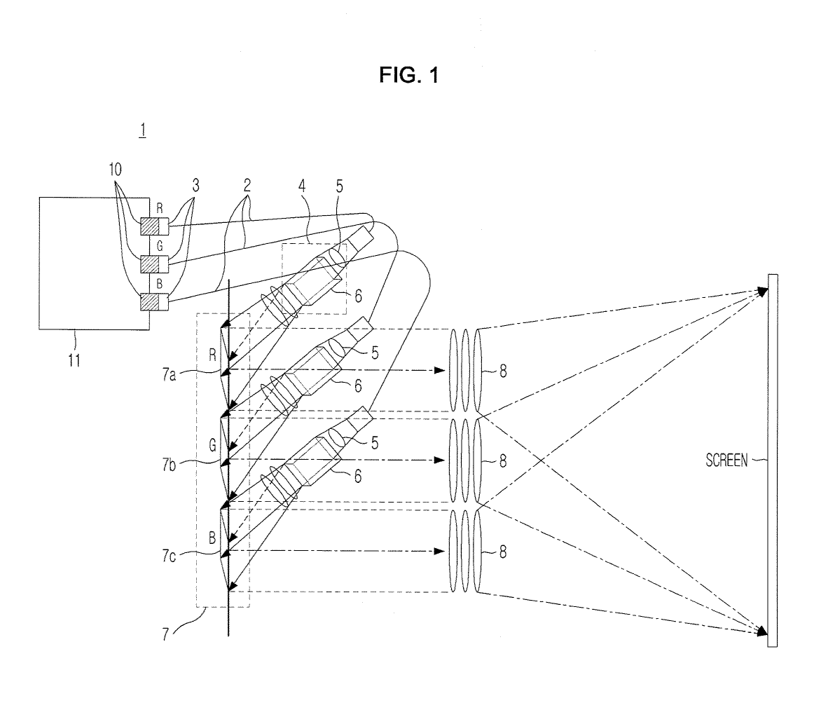

FIG. 1 is a view illustrating an apparatus for projecting an image in accordance with a preferred embodiment of the present invention.

An apparatus 1 for projecting an image in accordance with the preferred embodiment, as shown in FIG. 1, includes a light source unit 10, a light transmission unit 2 and 3, surface light source formation units 4, a digital micromirror device (DMD) 7, and a projection lens unit 8. In FIG. 1, the optical path of a laser beam is shown by an alternated long and short dash line.

The light source unit 10 includes light sources 10a, 10b, and 10c, which respectively emit beams having different wavelengths. The beams (hereinafter, referred to as ‘laser beams’) are R (Red), G (Green), and B (Blue) laser beams, but may be of other colors and/or may be different in number. The light transmission unit 2 and 3 includes optical fibers 2, through which the laser beams respectively pass, and a plurality of micro lenses 3 for respectively converging the laser beams. The micro lenses 3 are respectively provided at input terminals of the optical fibers 2. The laser beams, converged on the micro lenses 3, are respectively transmitted to the surface light source formation units 4 through the optical fibers 2.

The surface light source formation units 4 are installed at output terminals of the optical fibers 2, and uniformly convert the transmitted laser beams into surface light sources. Each of the surface light source formation units 4 includes a lens 5 and a light tube 6.

The lens 5 disperses the laser beam so that the laser beam is incident upon the light tube 6. The light tube 6 has a hollow hexahedral shape. When the laser beam dispersed by the lens 5 is incident upon the inside of the hollow light tube 6, the conversion of the laser beam into a surface light source is achieved. The inner four surfaces of the light tube 6 are made of a mirror.

The surface light source formation units 4 are disposed such that the R, G, and B laser beams are incident upon a plurality of DMD panels 7a, 7b, and 7c of the DMD 7 corresponding to the R, G, and B laser beams. The R, G, and B laser beams, converted into surface light sources, are incident upon the DMD panels 7a, 7b, and 7c of the DMD 7 at a designated angle. The DMD 7 includes three DMD panels 7a, 7b, and 7c. In this embodiment, the three DMD panels 7a, 7b, and 7c are arranged in a straight line. The three DMD panels 7a, 7b, and 7c modulate the incident laser beams into digital types, and then reflect the digital type laser beams at a designated angle.

The projection lens unit 8 is installed opposite to the DMD 7. The respective laser beams, reflected by the DMD panels 7a, 7b, and 7c, are incident upon three projection lens. Then, the laser beams are projected on a screen through the projection lens unit 8, thus forming an image.

As described above, the light source unit 10 of the apparatus 1 includes the laser light sources 10a, 10b, and 10c. The laser light sources 10a, 10b, and 10c have a high heating value, and thus a heat sink 11 for cooling the light source unit 10 is essentially required.

Although the above embodiment illustrates an apparatus for projecting an image using laser light sources, the present invention is not limited thereto and can be applied to cool light source units of various kinds of apparatuses for projecting an image.

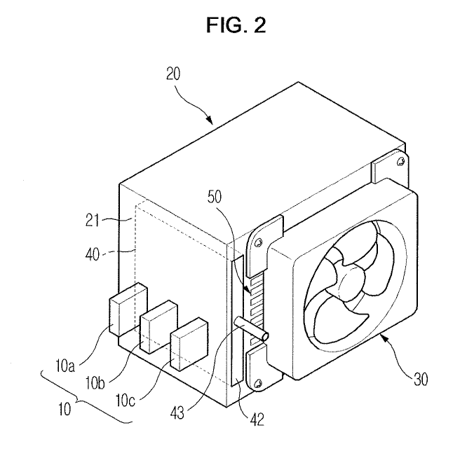

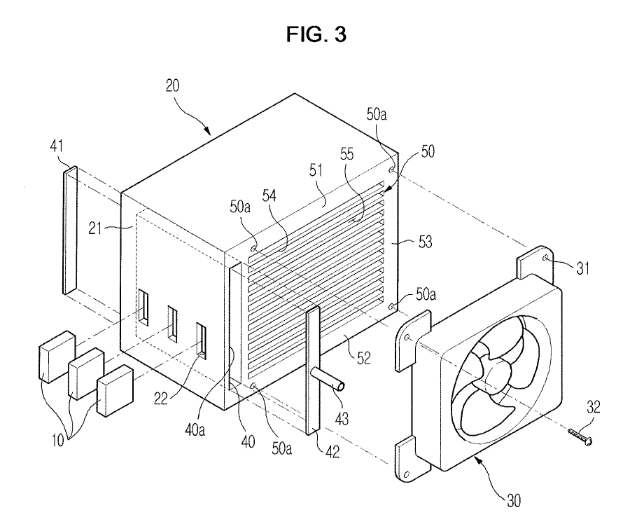

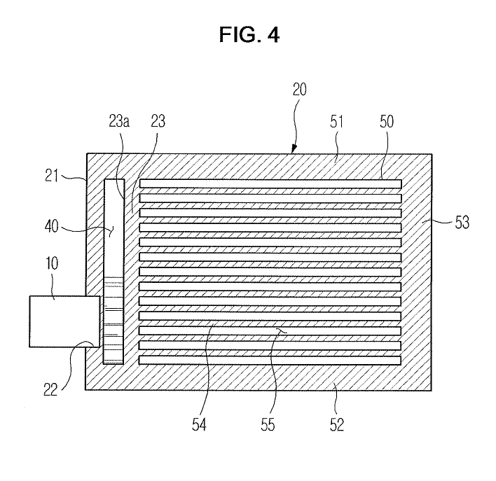

FIG. 2 is an assembled perspective view illustrating a light source unit and a heat sink for cooling the light source unit in the apparatus for projecting an image in accordance with the preferred embodiment of the present invention, FIG. 3 is an exploded perspective view of FIG. 2, and FIG. 4 is a cross-sectional view of FIG. 2.

The heat sink 11 for cooling the light source unit 10 of the apparatus 1 for projecting an image in accordance with the preferred embodiment includes a heat dissipation unit 20 for dissipating the heat of the light source unit 10, and a cooling fan 30 connected to one side of the heat dissipation unit 20.

The heat sink 11 of the present invention includes the above-described components of the apparatus for projecting an image, except for the light source unit 10.

The heat dissipation unit 20, as shown in FIGS. 2 to 4, is made of a metal and has an approximately rectangular parallelepiped shape. The heat dissipation unit 20 includes a chamber part 40 and a duct part 50, which are divided from each other by a diaphragm 23. The chamber part 40 is provided with covers 41 and 42 for closing an opening 40a of the chamber part 40.

Preferably, the heat dissipation unit 20 is made of a metal having a high thermal conductivity, such as aluminum, copper, and their alloys.

Holding parts 22 for holding the light source unit 10 therein are formed through one surface 21 of the heat dissipation unit 20. The holding parts 22 are provided at the approximately lower portion from the center of the heat dissipation unit 20, and serve to support the light source unit 10. The light source unit 10 is fixed to the holding parts 22 by a general connecting method, such as pressing, bonding, or connecting with screws.

The heat dissipation unit 20 includes the chamber part 40 having a designated space provided at the inner sides of the holding parts 22, and the duct part 50 having a designated space adjoining the chamber part 40. The diaphragm 23 for dividing the chamber part 40 and the duct part 50 from each other serves as a heat conduction part for transmitting the heat of the chamber part 40 to the duct part 50.

The chamber part 40 serves to promote the diffusion of heat, and is filled with a liquid and forms a vacuum.

In the case that the heat dissipation unit 20 is produced by casting, the chamber part 40 may be formed in the heat dissipation unit 20 without any separate member. However, in the case that the heat dissipation unit 20 is produced by extrusion molding so as to reduce production costs as the preferred embodiment, both side surfaces of the chamber part 40 are opened and thus a pair of the covers 41 and 42 made of a metal for closing the opening 40a is provided.

The covers 41 and 42 have an approximately enough size to close the opening 40a, and are preferably made of the same material as that of the heat dissipation unit 20 and connected to the heat dissipation unit 20 by fusion, melting, welding, or bonding, thus closing the opening 40a.

Here, a filling tube 43 for making the inside of the chamber part 40 into a vacuum state and injecting a liquid into the chamber part 40 therethrough is formed on at least one of the covers 41 and 42.

By injecting the liquid into the chamber part 40 after the inside of the chamber part 40 is made into the vacuum state, the evaporation point of the liquid is lowered and thus the heat transfer is more effectively achieved.

The liquid in the chamber part 40 may be water, or a volatile liquid, such as ethanol or acetone. When the heat of the light source unit 10 is transferred to the chamber part 40, the liquid is evaporated, and gas obtained by the evaporation of the liquid is condensed on a front surface 23a of the diaphragm 23 having a relatively low temperature and transfers the heat to the duct part 50.

The duct part 50, which serves to dissipate the heat transferred through the chamber part 40, includes frames 51, 52, and 53 on upper, lower, and rear surfaces thereof, and both sides of the duct part 50 are opened. Accordingly, air is forcibly blown through both opened sides of the duct part 50 by the driving of the cooling fan 30, and thus the heat transferred through the chamber part 40 is discharged to the outside.

Screw holes 50a for fixing the cooling fan 30 are formed through the frames 51, 52, and 53 at the edge of the duct part 50.

Heat dissipation fins 54 are formed integrally with the heat dissipation unit 20 when the heat dissipation unit 20 is molded. Air flow channels 55, in which air flows, are formed between the heat dissipation fins 54, and the heat, which is transmitted from the chamber part 40 and is then dissipated from the heat dissipation fins 54, is rapidly discharged to the outside through the air flow channels 55 by the driving of the cooling fan 30.

The higher the adherence of the heat dissipation fins 54 with the diaphragm 23, the heat dissipating effect of the heat dissipation fins 54 is improved. Since the diaphragm 23, the frames 51, 52, and 53 forming the duct part 50, and the heat dissipation fins 54 are molded integrally using the same material, the heat dissipation fins 54 of the present invention have an enhanced heat dissipating effect, compared with conventional heat dissipation fins.

Further, although the preferred embodiment describes the heat dissipation fins, which have a plate shape and are disposed on the duct part, the heat dissipation fins may have various corrugated shapes so as to rapidly dissipate heat through the increased surface area of the heat dissipation fins.

Accordingly, the duct part 50 includes the heat dissipation fins 54 formed therein and guides air, forcibly blown when the cooling fan 30 is driven, thereby inducing the air towards the heat dissipation fins 54 and enhancing a heat dissipating effect.

The cooling fan 30, which is an axial flow fan, is installed on the frames 51, 52, and 53 adjacent to the heat dissipation fins 54, and holes 31 corresponding to the screw holes 50a of the frames 51, 52, and 53 are formed through the edge of the cooling fan 30.

The cooling fan 30 rapidly cools the heat discharged from the heat dissipation fins 54. Then, air of a high temperature, having absorbed the heat generated from the light source unit 10, is discharged to the outside through the duct part 50, thereby preventing an increase of a temperature in the apparatus. If necessary, one or plural cooling fans 30 may be installed according to heat generation characteristics of the light source unit 10.

Hereinafter, a process for manufacturing the heat sink in accordance with the embodiment of the present invention will be described.

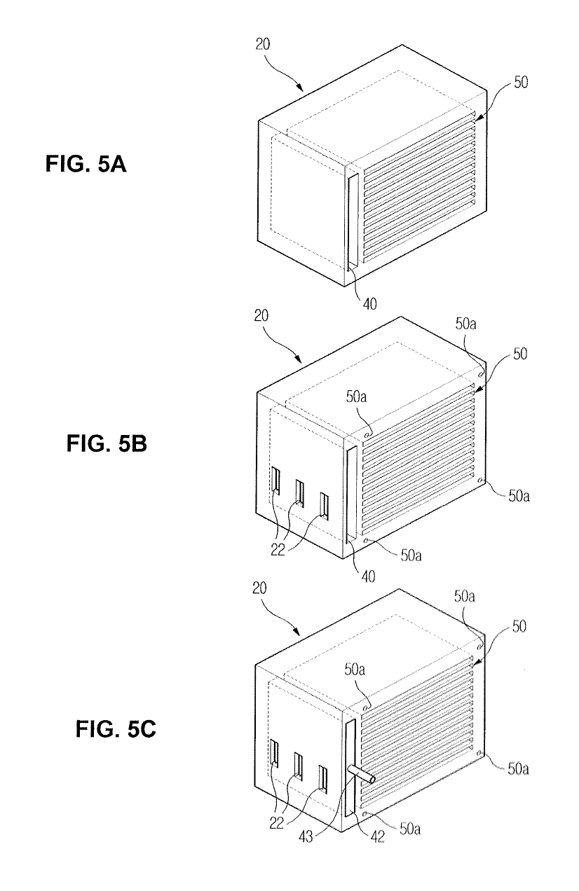

FIGS. 5A to 5C are views illustrating a process for manufacturing the heat sink in accordance with the preferred embodiment of the present invention.

As shown in FIG. 5A, the heat dissipation unit 20 is produced by extrusion molding using a general metal having a high thermal conductivity, such as aluminum, copper, and their alloys.

The heat dissipation unit 20 may be produced by investment casting, such as die casting. However, in the preferred embodiment, the heat dissipation unit 20 is produced by extrusion molding, which has a relatively simple process and thus reduces production costs.

That is, the heat dissipation unit 20 is obtained by cutting a heat dissipation member having a long length, produced through extrusion molding, to a designated size.

Thereafter, as shown in FIG. 5B, the holding parts 22 for holding the light source unit 10 therein are formed through one surface of the heat dissipation unit 20, and the screw holes 50a for fixing the cooling fan 30 are formed through the frames 51, 52, and 53.

Thereafter, the covers 41 and 42 are connected to the opening of the chamber part 40 so as to close the chamber part 40, the chamber part 40 is deflated through the filling tube 43 so that the inside of the chamber part 40 becomes a vacuum state, and then a liquid is injected into the chamber part 40 through the filling tube 43. Here, although the amount of the liquid may be changed according to design specification, it is preferable that the volume of the liquid is maintained to be approximately 50% of that of the chamber part 40.

The connection of the covers 41 and 42 to the chamber part 40 and the formation of the holding parts 22 and the screw holes 50a for installing the cooling fan 30 may be carried out in reverse order.

Thereafter, the cooling fan 30 is fixed to the heat dissipation unit 20 using screws 32, and the light source unit 10 is installed in the holding parts 22.

Next, a process for dissipating the heat of the light source unit using the heat sink in accordance with the preferred embodiment of the present invention will be described.

The heat of light source unit 10 is transferred to the chamber part 40 through the circumferences of the holding parts 22. The liquid in the chamber part 40 is heated by the heat transferred to the chamber part 40. Since the chamber part 40 maintains the vacuum state, the liquid is evaporated at a low temperature and thus a heat dissipating effect is enhanced.

The gas, obtained by the evaporation of the liquid, is condensed on the front surface 23a of the diaphragm 23 having a relatively low temperature and thus transfers heat to the diaphragm 23, and the heat transferred to the diaphragm 23 is transferred to the duct part 50 through the heat dissipation fins 54.

Then, the cooling fan 30 fixed to one side of the duct part 50 is driven, and the heat dissipated by the heat dissipation fins 54 is rapidly discharged to the outside through the air flow channels 55, thus cooling the heat dissipation fins 54.

The above-described heat sink allows the duct part to have a compact size and has the heat dissipation fins formed integrally with the duct part by extrusion molding, thus simplifying an assembly structure, reducing production costs, and increasing space utilization.

Further, the chamber part is formed between the light source unit and the duct unit and the liquid is injected into the inside of the chamber part in a vacuum state, thus increasing a cooling efficiency.

Since the chamber part is formed integrally with the heat dissipation unit when the heat dissipation unit is produced by extrusion molding, it is possible to increase space utilization and a production cost reducing effect.

Further, the cooling fan is connected directly to the heat dissipation unit made of a metal, thus preventing noise transferred by the cooling fan without an anti-vibration member.

Although the preferred embodiment describes the heat dissipation unit having the chamber part formed therein, the heat dissipation unit without the chamber part may be possible so as to reduce production costs.

Further, although the preferred embodiment describes the heat sink applied to an apparatus for projecting an image having laser light sources, the heat sink of the present invention is not limited to the laser light sources but may be applied to various heating elements requiring a heat dissipation structure, such an LED light source, a driving motor, and a semiconductor chip.

Further, although the preferred embodiment describes the heat sink applied to an apparatus for projecting an image having three light sources and the corresponding number of image panels for each of the light sources, the present invention may be applied to projection displays having a single light source, a color wheel and a image panel.

As apparent from the above description, the present invention provides a heat sink and an apparatus for projecting an image having the same, in which a duct part is compact-sized and heat dissipation fins are formed integrally with the duct part, thus simplifying an assembly structure, reducing production costs, and enhancing space utilization.

Further, since a chamber part is formed between a light source unit and the duct unit and a liquid is injected into the chamber part in a vacuum state, it is possible to increase the cooling efficiency of the light source unit.

Although embodiments of the invention have been shown and described, it would be appreciated by those skilled in the art that changes may be made in these embodiments without departing from the principles and spirit of the invention, the scope of which is defined in the claims and their equivalents.

What is claimed is:

1. A heat sink comprising a heat dissipation unit for cooling a light source unit comprising:
a heat dissipation unit including a duct part for forming a space, into which the heat of the light source unit is discharged, and
heat dissipation fins formed integrally with the duct part.

2. The heat sink according to claim 1, wherein the heat dissipation unit is produced by extrusion molding using a metal.

3. The heat sink according to claim 1, wherein holding parts for fixing the light source unit are formed on the heat dissipation unit.

4. The heat sink according to claim 1, further comprising a cooling fan connected directly to the heat dissipation unit so as to cool the heat dissipation fins.

5. The heat sink according to claim 1, wherein the heat dissipation unit further includes a chamber part provided between the light source unit and the duct part so as to promote the diffusion of heat.

6. The heat sink according to claim 5, wherein the chamber part maintains a vacuum state, and is filled with a designated amount of a liquid.

7. The heat sink according to claim 1, wherein the light source unit is applied to an apparatus for projecting an image.

8. The heat sink according to claim 7, wherein the light source unit includes laser light sources.

9. The heat sink according to claim 1, wherein the heat dissipation fins are formed integrally with the inside of the duct part.

10. An apparatus for projecting an image, comprising a light source unit, and a heat sink for cooling the light source unit, wherein the heat sink includes:
a heat dissipation unit including a duct part for forming a space, into which the heat of the light source unit is discharged, and a heat dissipation fins formed integrally with the duct part; and
a cooling fan connected directly to one side of the heat dissipation unit.

11. The apparatus according to claim 10, wherein:
the light source unit is held on one surface of the heat dissipation unit; and
the heat dissipation unit further includes a chamber part provided between the light source unit and the duct part so as to promote the diffusion of heat.

12. The apparatus according to claim 11, wherein the chamber part maintains a vacuum state, and is filled with a designated amount of a liquid.

13. The apparatus according to claim 10, wherein the light source unit includes laser light sources.

14. The apparatus according to claim 10, wherein the heat dissipation unit is produced by extrusion molding using a metal.

15. The apparatus according to claim 10, wherein the heat dissipation fins are formed integrally with the inside of the duct part.

16. The apparatus according to claim 10, wherein the light source unit is an LED unit.

17. The apparatus according to claim 16, wherein the LED unit comprises of at least of red, green and blue color.

18. The apparatus according to claim 10, wherein the light source unit is a laser diode unit.

19. The apparatus according to claim 18, wherein the laser diode unit comprises of at least red, green and blue color.

20. The apparatus according to claim 10, further comprising of at least three image panels for receiving and reflecting the light generated by the light source units.

21. The apparatus according to claim 20, wherein the image panels are DMD panels.

22. An apparatus for projecting an image comprising:
a light source unit;
a heat dissipation unit including a duct part for forming a space, into which the heat of the light source unit is discharged; and
a heat dissipation fins formed integrally with the duct part;

23. The apparatus according to claim 22, further comprising:
a cooling fan connected directly to one side of the heat dissipation unit.

24. The apparatus according to claim 22, wherein a chamber is formed integrally with the heat dissipation unit.

25. The apparatus according to claim 24, wherein at least a portion of the chamber is filled with a liquid.

26. The apparatus according to claim 25, wherein the liquid is water.

27. The apparatus according to claim 25, wherein the liquid is ethanol.

28. The apparatus according to claim 25, wherein the liquid is acetone.

29. The apparatus according to claim 24, wherein the chamber is in a vacuum state.

30. The apparatus according to claim 22, wherein the heat dissipating unit further includes a support part to support a light source unit.

31. The apparatus according to claim 30, wherein the light source unit comprises of either LED unit or a laser diode unit.

32. The apparatus according to claim 30, wherein the support is a cut out formed in the heat dissipation unit.

33. The apparatus according to claim 24, wherein the chamber is disposed between the light source and the duct part.

34. The apparatus according to claim 24, wherein the chamber is provided with a cover.

35. The apparatus according to claim 22, wherein the heat dissipating unit includes a connector to connect a fan to the heat dissipation unit.

36. The apparatus according to claim 30, wherein the support part is in direct thermal communication with the chamber.
